(19) United States
(12) Patent Application Publication
(10) Pub. No.: US 2005/0090032 A1
(43) Pub. Date: Apr. 28, 2005

(54) Method of manufacturing nitride semiconductor light emitting device

(76) Inventors: Je Won Kim, Seoul (KR); Joong Seo Kang, Kyungki-do (KR); Dong Joon Kim, Seoul (KR)

Correspondence Address: LOWE HAUPTMAN GILMAN & BERNER, LLP, Suite 310, 1700 Diagonal Road, Alexandria, VA, 22314, US

(21) Appl. No.: 10/776,228

(22) Filed: Feb. 12, 2004

(30) Foreign Application Priority Data
Oct. 28, 2003 (KR) 2003-75563

(51) Int. Cl. H01L 21/00; H01L 21/28; H01L 21/3205

(52) U.S. Cl. 438/46; 438/606

(57) ABSTRACT

Disclosed herein is a method of manufacturing a nitride semiconductor light emitting device. a nitride semiconductor crystal film is grown on a substrate. The nitride semiconductor crystal film has a composition represented as AlₓIn_{y}Ga_{(1-x-y)}N (0≦x≦1, 0≦y≦1, 0≦x+y≦1). After that, in order to remove an oxide film naturally formed on the nitride semiconductor crystal film, a surface treatment process is performed on the nitride semiconductor crystal film by making use of hydrogen gas or mixed gases containing hydrogen. Subsequently, on the nitride semiconductor crystal film there are successively formed a first conductive nitride semiconductor layer, an active layer, and a second conductive nitride semiconductor layer.

### BACKGROUND OF THE INVENTION

1. Field of the Invention

The present invention relates to a nitride semiconductor light emitting device, and more particularly to a method of manufacturing a nitride semiconductor light emitting device by growing a high quality nitride semiconductor layer on a substrate using homoepitaxy.

2. Description of the Related Art

Generally, nitride semiconductor light emitting devices are light emitting devices used for emitting light having a wavelength band around a blue or green wavelength, and made of semiconductors having a composition represented as AlₓIn_{y}Ga_{(1-x-y)}N (0≦x≦1, 0≦y≦1, 0≦x+y≦1).

A nitride semiconductor crystal layer (hereinafter, referred to as a nitride semiconductor layer) can be grown on a heterogeneous substrate, such as a sapphire (α-AI₂O₃) substrate or SiC substrate. The sapphire substrate, especially, is mainly used since it has the same hexagonal structure as gallium nitride (hereinafter, referred to as GaN), exhibits low cost compared with the SiC substrate, and is stable at high temperatures.

The sapphire substrate, however, has a lattice mismatch up to approximately 13% as well as a difference of thermal expansion coefficients up to approximately −34%, compared with gallium nitride, thereby inevitably causing strains in an interface region between the sapphire substrate and a GaN single crystal. Such strain results in a problem in that lattice defects and cracks may be generated within the crystal. These lattice defects and cracks make it difficult to grow a high quality nitride semiconductor, thus being a reason of deterioration in the life span and reliability of a finally manufactured nitride semiconductor light emitting device.

In order to solve the above problems, there is generally employed a heteroepitaxy method of forming a middle buffer layer on the sapphire substrate. As such a middle buffer layer, a low temperature nucleation layer, such as AlₓGa₁₋ₓN, is used. FIG. 1 is a sectional view illustrating a conventional nitride semiconductor light emitting device using the low temperature nucleation layer.

As shown in FIG. 1, the conventional nitride semiconductor light emitting device comprises a sapphire substrate 11, an AlN buffer layer 12, a first conductive nitride semiconductor layer 13, a multiple quantum well active layer 15, and a second conductive nitride semiconductor layer 17. On the upper surface of the second conductive nitride semiconductor layer 17 is formed an n-type electrode 19a, and on the upper surface of the first conductive nitride semiconductor layer 13 is formed a p-type electrode 19b. These electrodes 19a and 19b are formed at partial regions of the upper surfaces exposed to the outside via a mesa etching process.

The buffer layer 12 may be made of other materials than AlN, in accordance with the crystal character of a nitride semiconductor layer, which will be grown thereon. For example, the buffer layer 12 may be formed by a low temperature nucleation layer or ZnO layer satisfying a composition represented as AlₓGa₁₋ₓN.

In spite of the addition of such buffer layer 12, it is very difficult to realize a high quality crystal character from the conductive nitride semiconductor layers 13 and 17 and the active layer 15, which will be later grown, if there are differences of crystal structures and lattices between the buffer layer and adjacent other layers, or since a homogeneous GaN buffer layer itself is a low temperature nucleation layer having a poly-crystalline character. For example, in case of a nitride semiconductor layer formed on a low temperature GaN layer as a low temperature nucleation layer, it is known to have crystal defects to a level of 10⁹ to 10¹⁰/cm². Such a level of crystal defects may be a reason of deteriorating reliability of devices.

The formation of the buffer layer, further, inevitably requires to perform a thermal cleaning process on the sapphire substrate before the growth of the low temperature nucleation layer serving as the buffer layer. Since the low temperature nucleation layer may vary sensitively in its processing factors, such as the temperature and thickness of growth, it is considerably difficult to control these factors within appropriate ranges. After all, the formation of the buffer layer increases a process time and complicates process control.

As stated above, the above described conventional solution adopting the low temperature nucleation layer serving as the buffer layer is hardly successful in achievement of a high quality nitride semiconductor layer. Therefore, a technique of growing a GaN crystal film on a sapphire substrate by using an HVPE (Hydride Vapor Phase Epitaxy) method has recently been studied. The GaN crystal film can be advantageously grown to a high quality semiconductor layer having a mirror surface.

After the growth of the GaN crystal film has been stopped, however, it is liable to generate an undesired oxide film thereon in a ready step for the re-growth of a nitride semiconductor layer constituting a light emitting structure. For example, after the GaN crystal film is grown on the sapphire substrate by using the HVPE method, the nitride semiconductor layer constituting the light emitting structure is transferred into a new reactor chamber for allowing it to be grown by using an MOCVD (Metal Organic Chemical Vapor Deposition) method. In this course, the surface of the GaN crystal film is exposed to the atmosphere, thereby producing the oxide film. The resulting oxide film deteriorates crystal quality of the light emitting structure rather than advantageously affecting it.

Therefore, there has been required in the art a method of manufacturing a nitride semiconductor light emitting device, which is capable of employing a crystal film satisfying optimum requirements for the growth of a high quality semiconductor crystal layer constituting a light emitting structure.

### SUMMARY OF THE INVENTION

Therefore, the present invention has been made in view of the above problems, and it is an object of the present invention to provide a method of manufacturing a nitride semiconductor light emitting device, which is capable of achieving a light emitting structure featuring good crystal quality by growing a homogeneous nitride semiconductor crystal film on a substrate, the crystal film serving as a buffer layer instead of a low temperature nucleation layer.

In accordance with the present invention, the above and other objects can be accomplished by the provision of a method of manufacturing a nitride semiconductor light emitting device comprising the steps of: a) preparing a substrate for use in growth of nitride semiconductors; b) growing a nitride semiconductor crystal film on the substrate, the film having a composition represented as AlₓIn_{y}Ga_{(1-x-y)}N (0≦x≦1, 0≦y≦1, 0≦x+y≦1); c) performing a surface treatment process on the nitride semiconductor crystal film by making use of hydrogen gas or mixed gases containing hydrogen, in order to remove an oxide film formed on the nitride semiconductor crystal film; and d) successively forming a first conductive nitride semiconductor layer, an active layer, and a second conductive nitride semiconductor layer on the nitride semiconductor crystal film.

Preferably, the nitride semiconductor crystal film may have the same composition as that of the first conductive nitride semiconductor layer formed thereon, and the nitride semiconductor crystal film may be a gallium nitride film.

Preferably, the nitride semiconductor crystal film may have a thickness of 1 to 10 micrometers. If the thickness of the nitride semiconductor crystal film is less than 1 micrometer, it is difficult for it to successfully function as a crystal film for use in the formation of subsequent nitride semiconductor layers constituting a light emitting structure. On the other hand, if the thickness of the nitride semiconductor crystal film exceeds 10 micrometers, due to differences of lattice constants and thermal expansion coefficients between the nitride crystal film and sapphire substrate for use in the growth of the nitride semiconductor layers, the substrate is bent, thus preventing heat from being uniformly transmitted throughout the upper surface of the substrate. In a serious case, there is a possibility of damage to the substrate itself.

Preferably, the step b) may be performed by an HVPE (Hydride Vapor Phase Epitaxy) method. In this case, the manufacturing method of the present invention may further comprise the nitridation process step a′) of the substrate, before performing the step b).

Preferably, the step c) may be performed at a temperature not exceeding 800° C. by making use of hydrogen gas or mixed gases containing hydrogen, and after completing the step c), the manufacturing method of the present invention may further comprise the step c′) of performing a heat treatment process on the nitride semiconductor crystal film. The step c′) may be performed at a temperature of 100° C. to 1500° C. under the environment of gases including at least one selected from among a group consisting of Nitrogen, Hydrogen, and Ammonia.

Preferably, the step d) may be performed by an MOCVD (Metal Organic Chemical Vapor Deposition) method, and the substrate for use in growth of nitride semiconductors may be a sapphire substrate or SiC substrate.

As stated above, according to the present invention, after the nitride semiconductor crystal film is grown on the substrate suitable for the growth of a nitride semiconductor crystal film, such as a sapphire substrate, by using an HVPE method, nitride semiconductor layers are grown so as to constitute a light emitting structure, resulting in a good nitride semiconductor light emitting device having a low density of crystal defects. Especially, the present invention presents a solution of removing a disadvantageous oxide film, which is inevitably produced on the semiconductor crystal film between a process of forming the homogeneous nitride semiconductor crystal film serving as a buffer layer and a process of forming the nitride semiconductor layers constituting the light emitting structure.

For example, after the nitride semiconductor crystal film is grown by using an HVPE method, and before light emitting structure is grown by using an MOCVD or MBE method, as the nitride semiconductor crystal film is transferred from an HVPE reactor chamber to an MOCVD reactor chamber, an undesired oxide film is produced, thereby making the crystal growth of the nitride semiconductor layers constituting the light emitting structure impossible. In order to solve any drawbacks due to the undesired oxide film, the present invention further presents a solution of performing a surface treatment process on the nitride semiconductor crystal film by making use of hydrogen gas or mixed gases containing hydrogen before forming the nitride semiconductor layers.

### BRIEF DESCRIPTION OF THE DRAWINGS

The above and other objects, features and other advantages of the present invention will be more clearly understood from the following detailed description taken in conjunction with the accompanying drawings, in which:

FIG. 1 is a side sectional view illustrating a nitride semiconductor light emitting device in accordance with the prior art;

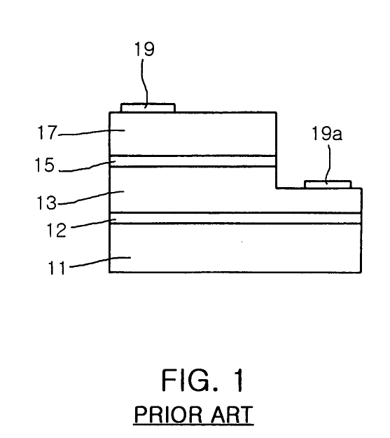

FIG. 2 is a flow chart explaining a manufacturing method of a nitride semiconductor light emitting device in accordance with a preferred embodiment of the present invention; and

FIGS. 3a to 3f are sectional views illustrating the sequential steps of manufacturing the nitride semiconductor light emitting device in accordance with the preferred embodiment of the present invention.

### DESCRIPTION OF THE PREFERRED EMBODIMENTS

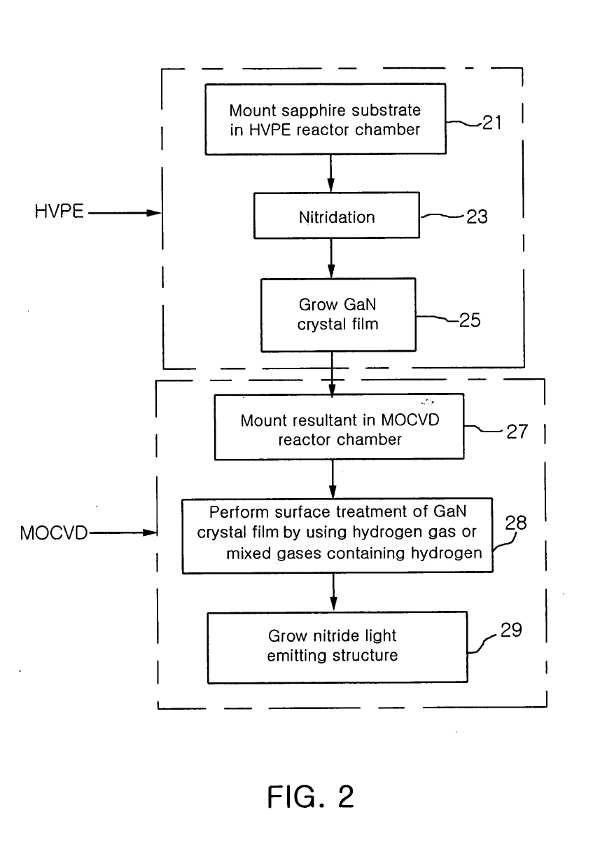

FIG. 2 is a flow chart explaining a manufacturing method of a nitride semiconductor light emitting device in accordance with a preferred embodiment of the present invention.

The present embodiment illustrates the combination of a process of forming a GaN crystal film on a substrate by using an HVPE method and a process of forming a light emitting structure by using an MOCVD method.

The manufacturing method of the nitride semiconductor light emitting device in accordance with the present embodiment, as shown in FIG. 2, begins with the step 21 of mounting a sapphire substrate in an HVPE reactor chamber for use in the HVPE method. The sapphire substrate is used for the growth of a nitride semiconductor crystal, and may be substituted with other substrates, such as an SiC substrate.

Next step 23 is a nitridation process performed on the surface of the sapphire substrate. This nitridation process step 23 is for achieving a good surface state suitable for the growth of a GaN crystal film. Generally, this step can be performed by supplying Ammonia gas into the HVPE reactor chamber.

The term “nitridation” used herein means a process of supplying mixed gases containing nitrogen onto the surface of a substrate so as to form a very thin AlN layer on the substrate, thereby achieving modification of the surface of the substrate. It should be understood that this nitridation process is considerably different from a conventional process of intentionally forming an AlN buffer layer.

Subsequently, the step 25 of growing a GaN crystal film on the surface nitridated sapphire substrate is performed. The GaN crystal film grown in this step can be understood not to be a crystal film constituting a light emitting structure, but a homogeneous buffer layer of the crystal layer, as a substitute for a conventional heterogeneous buffer layer. The GaN crystal film grown in this step preferably has a thickness of 1 to 10 micrometers. If the thickness of the GaN crystal film is less than 1 micrometer, it is difficult for it to successfully function as a buffer layer. On the other hand, if the thickness of the GaN crystal film exceeds 10 micrometers, due to differences of lattice constants and thermal expansion coefficients between the GaN crystal film and sapphire substrate, the substrate is bent, thus preventing heat from being uniformly transmitted throughout the upper surface of the substrate. In a serious case, there is a possibility of damage to the substrate itself.

By virtue of the fact that the GaN crystal film is directly formed on the sapphire substrate by using both the HVPE method and nitridiation process as stated above, it is possible to realize a good crystal layer having a considerably reduced density of defects in relation with a nitride semiconductor layer, which will be formed on the GaN crystal film. The nitride semiconductor layer constituting a light emitting structure is formed by using an MOCVD method.

The process of forming the light emitting structure using the MOCVD method employable in the present invention begins with the step 27 of mounting the GaN crystal film formed on the sapphire substrate inside an MOCVD reactor chamber. Using the MOCVD method it is easy to add desired conductive foreign substances and adjust film thickness, and thus it is generally used to form a light emitting structure. Alternatively, an MBE (Molecular Beam Epitaxy) method may be employed. As the GaN crystal film is transferred into the MOCVD reactor chamber, an undesired oxide film is produced at the surface of the GaN crystal film. Further, even if the GaN cyrstal film is not transferred from one reactor chamber to the other reactor chamber, since the GaN crystal film is adapted to experience two different growth processes, the above oxide film may be produced due to the variation of other exterior environment factors. The oxide film adversely affects the crystal growth of a subsequent light emitting structure, thus having to be removed through an additional process.

As such a removal process of the oxide film, the present invention introduces a surface treatment process for use in the step 28 using hydrogen gas or mixed gases containing hydrogen. According to the surface treatment process employed in the present invention, the GaN crystal film, formed on the sapphire substrate, is processed within the MOCVD reactor chamber by using hydrogen gas or mixed gases containing hydrogen so as to allow the oxide film formed on the surface thereof to be removed. The gases for use in this process in order to remove the oxide film may be hydrogen gas or mixed gases consisting of Ammonia, Nitrogen and hydrogen. This surface treatment process is preferably performed at a temperature not exceeding 800° C. in consideration of a conventional etching time (normally, several tens of minutes to several hours). Where the surface treatment temperature exceeds 800° C., there is a risk of causing an etching process to proceed up to the GaN crystal film even after being completed on the oxide film. It was confirmed that, when the GaN crystal film is etched, it shows a reduction in a reflectance ratio of the mirror surface thereof.

More preferably, the above surface treatment process can be performed in combination with a subsequent heat treatment process. The heat treatment process employable in the present invention is for improving the surface condition of the GaN crystal film, which was processed by hydrogen gas or mixed gases containing hydrogen so as to allow the oxide film formed thereon to be removed. Preferably, the heat treatment process can be performed at a temperature of 100° C. to 1500° C. under the environment of gases including at least one selected from among a group consisting of Nitrogen, Hydrogen and Ammonia.

After completing the heat treatment process, the MOCVD process is performed in the step 29 for growing a light emitting structure. In this process, similar to the formation process of a conventional light emitting structure, a first conductive nitride semiconductor layer, an active layer, and a second conductive nitride semiconductor layer are grown in turn. Since the light emitting structure resulting from the MOCVD process is directly formed on the GaN crystal film, it can result in a reduced density of defects and achieve a light emitting device having a more improved reliability on the basis of its good crystal quality.

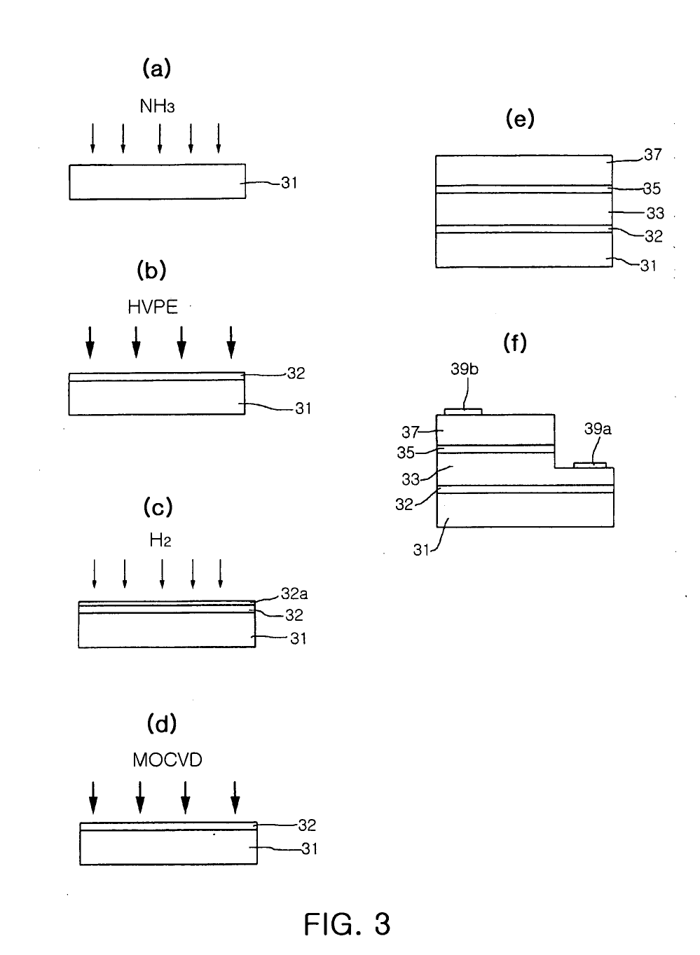

FIGS. 3a to 3f are sectional views illustrating the sequential steps of manufacturing the nitride semiconductor light emitting device in accordance with the preferred embodiment of the present invention.

As shown in FIG. 3a, a sapphire substrate 31 is first prepared, and then the upper surface of the sapphire substrate 31 is processed by performing a nitridation process in order to achieve a surface suitable for the growth of a GaN crystal film, designated as reference numeral 32 in FIG. 3b. This step is performed in such a manner that it provides Ammonia gas to the sapphire substrate 31 with a certain partial pressure. In the course of providing Ammonia gas to the sapphire substrate 31, a thin AlN film can be formed on the sapphire substrate 31, thereby enabling the formation of a high quality GaN crystal film.

As shown in FIG. 3b, the step of forming the nitride semiconductor crystal film 32 on the surface nitridated sapphire substrate 31 by using the HVPE method is successively performed. The nitride semiconductor crystal film 32 is preferably formed to have a thickness of 1 to 10 micrometers. Although the nitride semiconductor crystal film 32 is made of gallium nitride in the preferred embodiment of the present invention, it is not limited thereto. In order to achieve an optimum surface crystal condition for the formation of a light emitting structure, it is preferable to form the nitride semiconductor crystal film 32 by making use of un-doped nitride, which has the same composition as the first conductive nitride semiconductor layer to be directly grown on the sapphire substrate 31. Therefore, the nitride semiconductor crystal film 32 formed in this step may be a crystal film, which is made of nitride having a composition represented as AlₓIn_{y}Ga_{(1-x-y)}N (0≦x≦1, 0≦y≦1, 0≦x+y≦1). This composition is the same as that of the first conductive semiconductor layer.

After completing the growth of the nitride semiconductor crystal film and before proceeding the growth of a subsequent light emitting structure, as shown in FIG. 3c, an oxide film 32a is inevitably produced on the surface of the nitride semiconductor crystal film 32 due to the variation of external environmental factors. That is, since the nitride semiconductor crystal film 32 is grown by using the HVPE method, and the light emitting structure is grown by using the MOCVD method, the sapphire substrate 31 formed with the nitride semiconductor crystal film 32 is exposed to the atmosphere when it is transferred from the HVPE reactor chamber to the MOCVD reactor chamber for forming the above light emitting structure, thereby causing the oxide film 32a to be produced on the surface thereof as shown in FIG. 3c. The oxide film 32a makes it difficult to form the semiconductor layers constituting the light emitting structure. As can be seen from the above description, the formation of the light emitting crystal layer using the GaN crystal film has a limit in its commercialization by reason of inevitable stop in the growth process and of the oxide film produced in the transfer course between different reactor chambers.

The present invention, however, can solve the above described oxide film problem through a surface treatment process wherein the oxide film 32a on the nitride semiconductor crystal film 32 is removed by using hydrogen gas or mixed gases containing hydrogen. Preferably, this surface treatment process is performed at a temperature not exceeding 800° C. in order to prevent the nitride semiconductor crystal film from being etched. Furthermore, in order to improve the surface condition of the nitride semiconductor crystal film in a state wherein the oxide film is removed therefrom through the surface treatment process, a heat treatment process can be additionally performed at a temperature of 100° C. to 1500° C. under the environment of gases including at least one selected from among a group consisting of Nitrogen, Hydrogen and Ammonia.

Subsequently, the light emitting structure is formed by the MOCVD method as shown in FIG. 3d. This process may be performed by an MBE method instead of the MOCVD method. The light emitting structure resulting from this process is shown in FIG. 3e.

As shown in FIG. 3e, the light emitting structure comprises a first conductive nitride semiconductor layer 33, active layer 35, and second conductive nitride semiconductor layer 37, which are successively stacked in multiple layers. By virtue of the fact that the light emitting structure is formed on the nitride semiconductor crystal film 32, it can be formed to have good crystal quality featuring a considerably low density of defects. Especially, since the first conductive nitride semiconductor layer 33 comes into direct contact with the nitride semiconductor crystal film 32, in order to achieve the good crystal quality as stated above, the nitride semiconductor crystal film 32 preferably has the same composition as that of the first conductive nitride semiconductor layer 33.

In the next step, partial side portions of the second conductive nitride semiconductor layer 37 and active layer 35 are removed via a mesa etching process, thereby causing a partial upper surface region of the first conductive nitride semiconductor layer 33 to be exposed to the outside. At the exposed upper surface region of the first conductive nitride semiconductor layer 33 and at a certain region of the upper surface of the second conductive nitride semiconductor layer 37 are formed first and second electrodes 39a and 39b, respectively. In this way, a nitride semiconductor light emitting device can be completed as shown in FIG. 3f. The light emitting device obtained according to the manufacturing method of the present invention has the nitride semiconductor crystal film directly formed on the substrate, resulting in good nitride semiconductor layers having a considerably low density of crystal defects by virtue of homoepitaxy or other similar junction methods. Therefore, it will be clearly understood that a non-light emitting region of the light emitting device is minimized thus considerably improving light emission efficiency thereof.

As apparent from the above description, the present invention provides a method of manufacturing a nitride semiconductor light emitting device. According to the manufacturing method, a nitride semiconductor crystal film is grown on a substrate for use in the growth of a nitride semiconductor crystal, such as a sapphire substrate, by an HVPE method. After removing an oxide film naturally produced on the nitride semiconductor crystal film, nitride semiconductor layers constituting a light emitting structure are grown, resulting in a good nitride semiconductor light emitting device having a low density of crystal defects. Therefore, according to the present invention, it is possible to achieve a light emitting device having good crystal quality thus improving reliability thereof, and to increase light emission efficiency by virtue of a reduction in a non-light emitting region, which is conventionally produced in the device due to crystal defects.

Although the preferred embodiments of the present invention have been disclosed for illustrative purposes, those skilled in the art will appreciate that various modifications, additions and substitutions are possible, without departing from the scope and spirit of the invention as disclosed in the accompanying claims.

1. A method of manufacturing a nitride semiconductor light emitting device comprising the steps of:
a) preparing a substrate for use in growth of nitride semiconductors;
b) growing a nitride semiconductor crystal film on the substrate, the film having a composition represented as AlₓIn_{y}Ga_{(1-x-y)}N (0≦x≦1, 0≦y≦1, 0≦x+y≦1);
c) performing a surface treatment process on the nitride semiconductor crystal film by making use of hydrogen gas or mixed gases containing hydrogen, in order to remove an oxide film formed on the nitride semiconductor crystal film; and
d) successively forming a first conductive nitride semiconductor layer, an active layer, and a second conductive nitride semiconductor layer on the nitride semiconductor crystal film.

2. The method as set forth in claim 1, wherein the nitride semiconductor crystal film has the same composition as that of the first conductive nitride semiconductor layer formed thereon.

3. The method as set forth in claim 1, wherein the nitride semiconductor crystal film is a gallium nitride (GaN) film.

4. The method as set forth in claim 1, wherein the nitride semiconductor crystal film has a thickness of 1 to 10 micrometers.

5. The method as set forth in claim 1, wherein the step b) is performed by an HVPE (Hydride Vapor Phase Epitaxy) method.

6. The method as set forth in claim 5, further comprising the nitridation process step a′) of the substrate, before performing the step b).

7. The method as set forth in claim 1, wherein the step c) is performed at a temperature not exceeding 800° C. by making use of hydrogen gas or mixed gases containing hydrogen.

8. The method as set forth in claim 1, further comprising the step c′) of performing a heat treatment process on the nitride semiconductor crystal film, after completing the step c),
wherein the step c′) is performed at a temperature of 100° C. to 1500° C. under the environment of gases including at least one selected from among a group consisting of Nitrogen, Hydrogen, and Ammonia.

9. The method as set forth in claim 1, wherein the step d) is performed by an MOCVD (Metal Organic Chemical Vapor Deposition) method.

10. The method as set forth in claim 1, wherein the substrate for use in growth of nitride semiconductors is a sapphire substrate or SiC substrate.
